(19) United States
(12) Patent Application Publication
(10) Pub. No.: US 2024/0035151 A1
(43) Pub. Date: Feb. 1, 2024

(54) METHODS OF SELECTIVE DEPOSITION OF MOLYBDENUM

(71) Applicant: Applied Materials, Inc., Santa Clara, CA (US)

(72) Inventors: Rand Haddadin, Gilbert, AZ (US); Kunal Bhatnagar, Chandler, AZ (US); Mohith Verghese, Phoenix, AZ (US); Jose Alexandro Romero, Scottsdale, AZ (US); Aniruddh Shekhawat, Tempe, AZ (US)

(73) Assignee: Applied Materials, Inc., Santa Clara, CA (US)

(21) Appl. No.: 18/222,587

(22) Filed: Jul. 17, 2023

Related U.S. Application Data
(60) Provisional application No. 63/392,773, filed on Jul. 27, 2022.

(51) Int. Cl. C23C 16/06; C23C 16/04; C23C 16/40

(52) U.S. Cl. CPC C23C 16/06; C23C 16/045; C23C 16/40

(57) ABSTRACT

Methods for selective deposition are described herein. The methods include depositing an oxide on a first portion of a substrate surface selected from the group consisting of a metal surface, a metal nitride surface and a metal silicide surface. The methods further comprise selectively depositing a molybdenum film on a second portion of the substrate surface that does not have the oxide deposited thereon.

### CROSS-REFERENCE TO RELATED APPLICATIONS

This application claims priority to United States Provisional Application No. 63/392,773, filed Jul. 27, 2022, the entire disclosure of which is hereby incorporated by reference herein.

### TECHNICAL FIELD

Embodiments of the disclosure generally relate to methods of selective deposition of molybdenum on a metal surface or a metal nitride surface. Specific embodiments of the disclosure are directed to methods of selective deposition which utilize lanthanum oxide for selective deposition in patterned deposition and gap fill applications.

### BACKGROUND

The semiconductor industry faces many challenges in the pursuit of device miniaturization including the rapid scaling of nanoscale features. Such challenges include the fabrication of complex devices, often using multiple lithography steps and etch processes. Furthermore, the semiconductor industry needs low cost alternatives to high cost EUV for patterning complex architectures. To maintain the progress of device miniaturization and keep chip manufacturing costs down, selective deposition has shown promise. It has the potential to remove costly lithographic steps by simplifying integration schemes.

Selective deposition of materials can be accomplished in a variety of ways. For instance, some processes may have inherent selectivity to surfaces based on their surface chemistry. These processes are rare, and typically specific to the reactants used, materials formed and the substrate surfaces.

In addition, as the dimensions of devices continue to shrink, so does the gap/space between the devices, increasing the difficulty to physically isolate the devices from one another. Filling in the high aspect ratio trenches/spaces/gaps between devices which are often irregularly shaped with high-quality dielectric materials is becoming an increasing challenge to implementation with existing methods including gap fill, hardmasks and spacer applications. Selective deposition methods typically include depositing a mask material on a substrate and patterning the mask material to form a patterned mask. Regions of the substrate may then be exposed though the patterned mask after the patterning of the mask. The patterned mask may be removed from the substrate to expose non-implanted regions of the substrate and a material may be selectively deposited on selected regions of the substrate. However, these methods utilizing a mask material, patterning the mask material and removing the mask require multiple process steps in several process flows.

There is a need for new molybdenum deposition processes which increase selectivity of molybdenum deposition on certain oxides compared to metallic surfaces that utilize fewer process steps than existing methods utilizing deposition and removal of mask materials.

### SUMMARY

One or more embodiments of the disclosure are directed to a method of selective deposition. The method comprises depositing an oxide on a first portion of a substrate surface selected from the group consisting of a metal surface, a metal nitride surface, a metal silicide surface and combinations thereof; and selectively depositing a molybdenum film on a second portion of the substrate surface that does not have the oxide deposited thereon.

In some embodiments, a method of filling gap in a substrate. In one or more embodiments, a method of filling a gap in a substrate comprises depositing an oxide layer on a sidewall surface of the gap, the sidewall surface comprising a surface selected from the group consisting of a metal surface, a metal nitride surface, a metal silicide surface and combinations thereof; and depositing molybdenum on a bottom surface of the gap that does not have the oxide layer deposited thereon.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates an exemplary substrate during processing according to one or more embodiment of the disclosure;

FIG. 2 illustrates an exemplary processing method according to one or more embodiment of the disclosure;

FIG. 3A illustrates an exemplary substrate having a feature;

FIG. 3B illustrates the substrate having a feature shown in FIG. 3A with an oxide layer on the sidewalls; and

FIG. 3C illustrates the substrate having a feature shown in FIG. 3B with a molybdenum layer in the feature.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

Further, a “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers.

Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used herein, a “patterned substrate” refers to a substrate with a plurality of different material surfaces. In some embodiments, a patterned substrate comprises a first surface and a second surface. In some embodiments, the first surface comprises an oxide and the second surface comprises a metal, a metal nitride and/or a metal silicide.

As used in this specification and the appended claims, the terms “reactive gas”, “process gas”, “precursor”, “reactant”, and the like, are used interchangeably to mean a gas that includes a species which is reactive with a substrate surface. For example, a first “reactive gas” may simply adsorb onto the surface of a substrate and be available for further chemical reaction with a second reactive gas.

Embodiments of the disclosure provide methods of selective deposition which utilize lanthanum oxide (La₂O₃).

As used in this specification and the appended claims, the term “selectively depositing on a first surface over a second surface”, and the like, means that a first amount of a film or layer is deposited on the first surface and a second amount of film or layer is deposited on the second surface, where the second amount of film is less than the first amount of film, or no film is deposited on the second surface. The term “over” used in this regard does not imply a physical orientation of one surface on top of another surface but rather a relationship of the thermodynamic or kinetic properties of the chemical reaction with one surface relative to the other surface. For example, selectively depositing a molybdenum film onto a metal surface over an oxide surface means that the molybdenum film deposits on the metal surface and less or no molybdenum film deposits on the oxide surface; or that the formation of the molybdenum film on the metal surface is thermodynamically or kinetically favorable relative to the formation of a molybdenum film on the oxide surface.

In some embodiments, “selectively” means that the subject material forms on the target surface at a rate greater than or equal to about 10x, 15x, 20x, 25x, 30x, 35x, 40x, 45x or 50x the rate of formation on the non-selected surface. Stated differently, the selectivity for the target material surface relative to the non-selected surface is greater than or equal to about 10:1, 15:1, 20:1, 25:1, 30:1, 35:1, 40:1, 45:1 or 50:1.

According to one or more embodiments, selective deposition employs the use of an oxide layer in which the oxide layer is formed on substrate materials upon which deposition is to be avoided with negligible impact to the target substrate material. A film can be deposited on the target substrate material while deposition on other substrate materials is minimized or prevented by the oxide layer.

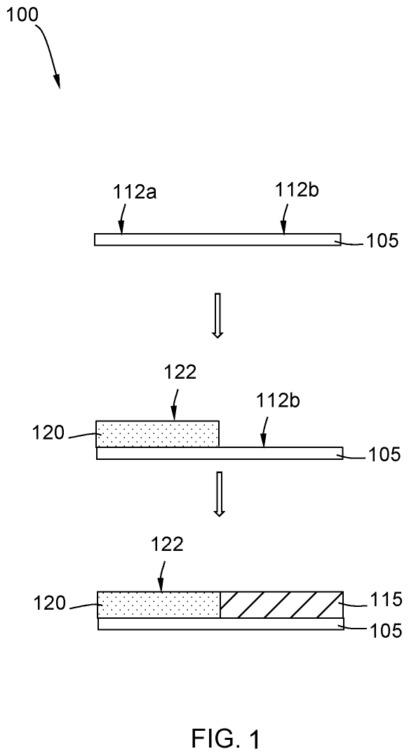

Referring to FIG. 1, one or more embodiment of the disclosure is directed to a processing method 100. A substrate 105 comprises a surface including a first portion 111a and a second portion 112b. Upon deposition of an oxide layer 120 on the first portion 112a of the substrate 105, the second material 120 has an oxide surface 122. The second portion 112b comprises the material of the substrate 105 and the first portion 112a of the substrate comprises the oxide surface 122.

In some embodiments, the substrate 105 and the second portion 112b of the substrate surface is selected from a metal surface, a metal nitride surface, a metal silicide surface and combinations thereof. In one or more embodiments, the metal comprises one or more tungsten, titanium, aluminum, lanthanum and molybdenum. In some embodiments, the metal nitride surface and metal silicide surface comprise one or more of TiN, MoN, LaN, TiSiN, TaN, TaSiN, MoSix, TaSiₓ, and WN. In specific embodiments, the metal nitride surface comprises TiN.

The oxide according to one or more embodiments is selected from the group consisting of SiO₂, Al₂O₃, ZrO₂, HfO₂, La₂O₃ and combinations thereof. In some embodiments, the oxide is deposited utilizing a process selected from the group consisting of atomic layer deposition (ALD), chemical vapor deposition (CVD), pulsed chemical vapor deposition (pCVD) and physical vapor deposition (PVD). In specific embodiments, the oxide surface comprises lanthanum oxide (La₂O₃).

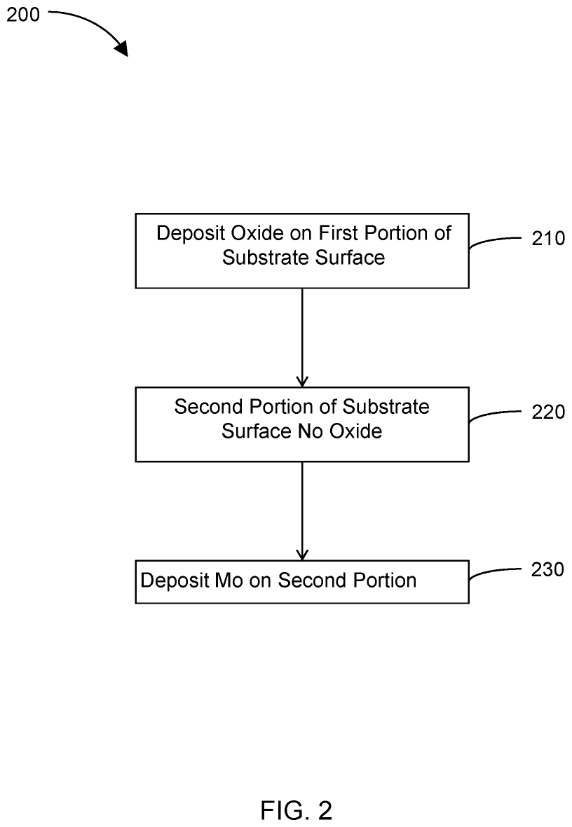

Thus, referring to FIG.2, according to one or more embodiments, a method 200 comprises at operation 210 depositing an oxide on a first portion of a substrate surface. Shown at 220 is a second portion of the substrate surface not having an oxide surface. At operation 230, molybdenum is deposited on the second portion of the substrate surface that does not have the oxide thereon. The molybdenum according to one or more embodiments is deposited by PVD, CVD, pCVD or ALD. Suitable molybdenum precursors included, but are not limited to MoCl₅, MoO₂Cl₂, Mo0Cl₄, and MoF₆.

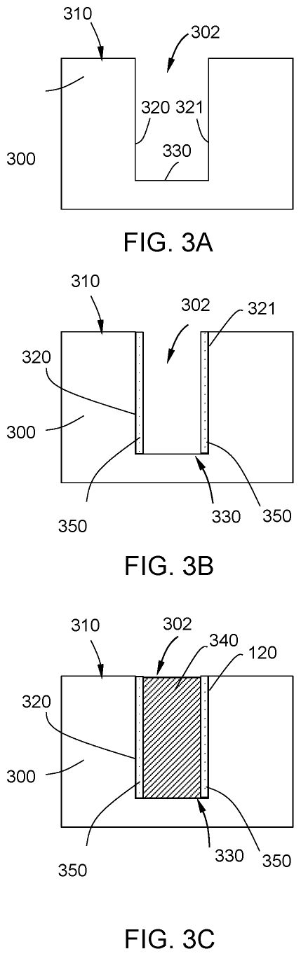

In some embodiments, the substrate comprises a feature, such as a via. Referring now to FIGS. 3A-C, an embodiment is shown in which a gap 302 (or via) in a substrate 300 is shown as being filled, such as in a bottom up gap fill process. FIG. 3A shows a substrate 300 having a top surface 310, a gap 302 (or via) having a first sidewall surface 320, a second sidewall surface 321 and a bottom surface 330.

In one or more embodiments of the method, after the oxide layer 120 has been deposited, the method comprises selectively depositing a molybdenum film 115 on the second portion 112b of the substrate surface that does not have the oxide deposited thereon, as shown in FIG. 1 as the second surface 112b of the substrate. The presence of the oxide layer 120 layer inhibits or prevents deposition at on the oxide surface, and therefore, molybdenum is selected deposited on the substrate 105.

According to some embodiments, selectively depositing the molybdenum film 115 comprises a pulsed chemical vapor deposition (pCVD) process or an atomic layer deposition (ALD) process).

In one or more embodiments, a method of filling the gap 302 (or via) in the substrate 300 comprises depositing an oxide a sidewall surface of the gap 302. In the embodiment shown the oxide layer 350 is deposited on a first sidewall surface 320 and an opposed second sidewall surface 321 defining the gap 302 (or via). The gap 302 further comprises a bottom surface 330 which does not have the oxide layer 350 deposited thereon. In FIG. 3C, a molybdenum film 340 is deposited on the bottom surface 330, filling the gap 302 between the first sidewall surface 320 and the second sidewall surface 321 having the oxide layer 350 thereon. In one or more embodiments, the bottom surface comprises a surface selected from the group consisting of a metal surface, a metal nitride surface, a metal silicide surface and combinations thereof.

According to one or more embodiments, the metal comprises one or more of tungsten, titanium, aluminum, lanthanum and molybdenum. In some embodiments, the metal nitride and metal silicide surfaces comprise one or more of TiN, MoN, LaN, TiSiN, TaN, TaSiN, MoSix, TaSix, and WN. In some embodiments the oxide is selected from the group consisting of SiO₂, Al₂O₃, ZrO₂, HfO₂, La₂O₃ and combinations thereof.

In one or more embodiments, the oxide is deposited utilizing a process selected from the group consisting of atomic layer deposition (ALD), chemical vapor deposition (CVD), pulsed chemical vapor deposition (pCVD) and physical vapor deposition (PVD). In some embodiments, selectively depositing the molybdenum film comprises a pulsed chemical vapor deposition (pCVD) process. In some embodiments, depositing the molybdenum film comprises an atomic layer deposition (ALD) process).

In specific embodiments, the bottom surface 330 comprises titanium nitride and the oxide comprises La₂O₃.

In embodiments that utilize an ALD process to deposit molybdenum, there is a first pulse of a molybdenum precursor a purge, a hydrogen (H2) pulse, purge of the hydrogen (H₂), and then the process is repeated until the desired layer thickness is obtained. In a pulsed CVD (pCVD process, a molybdenum precursor and hydrogen (H₂) gas is flowed together, and then the molybdenum precursor flow is terminated and only the hydrogen (H₂) gas is flowed for a single cycle. This cycle is repeated until the desired film thickness is achieved.

Exemplary, non-limiting deposition temperatures to advantageously provide for selective molybdenum deposition are in a range of 450° C. to 600° C. Suitable deposition pressures to advantageously provide for selective molybdenum deposition are in a range of from 15 Torr to 50 Torr. Suitable hydrogen flows to advantageously provide for selective molybdenum deposition are in range of from 5 slm to 30 slm. For pCVD processes, the molybdenum precursor is pulsed for a time in a range of 0.1 seconds to 5 seconds.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

In some embodiments, the selectivity improvement is evident relative to process which utilizes an oxide to cover a portion of the substrate. In some embodiments, the deposition rate of the film on a substrate that does not have the oxide thereon is at least 5% greater, at least 10% greater, at least 20% greater, at least 30% greater, at least 40% greater or at least 50% greater than the deposition rate on a substrate cleaned with hydrogen plasma.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of selective deposition, the method comprising:
depositing an oxide on a first portion of a substrate surface selected from the group consisting of a metal surface, a metal nitride surface, a metal silicide surface and combinations thereof; and
selectively depositing a molybdenum film on a second portion of the substrate surface that does not have the oxide deposited thereon.

2. The method of claim 1, wherein the metal comprises one or more of tungsten, titanium, aluminum, lanthanum and molybdenum.

3. The method of claim 1, wherein the metal nitride and metal silicide surfaces comprise one or more of TiN, MoN, LaN, TiSiN, TaN, TaSiN, MoSiₓ, TaSiₓ, and WN.

4. The method of claim 1, wherein the oxide is selected from the group consisting of SiO₂, Al₂O₃, ZrO₂, HfO₂, La₂O₃ and combinations thereof.

5. The method of claim 4, wherein the oxide is deposited utilizing a process selected from the group consisting of atomic layer deposition (ALD), chemical vapor deposition (CVD), pulsed chemical vapor deposition (pCVD) and physical vapor deposition (PVD).

6. The method of claim 1, wherein selectively depositing the molybdenum film comprises a pulsed chemical vapor deposition (pCVD) process.

7. The method of claim 1, wherein selectively depositing the molybdenum film comprises an atomic layer deposition (ALD) process).

8. The method of claim 1, wherein the first portioncomprises titanium nitride.

9. The method of claim 8, wherein the oxide comprises La2O3.

10. The method of claim 1, wherein the substrate surface comprises a feature.

11. The method of claim 10, where the feature comprises a via

12. A method of filling a gap in a substrate, the method comprising:
depositing an oxide layer on a sidewall surface of the gap, the sidewall surface comprising a surface selected from the group consisting of a metal surface, a metal nitride surface, a metal silicide surface and combinations thereof; and
depositing molybdenum on a bottom surface of the gap that does not have the oxide layer deposited thereon.

13. The method of claim 12, wherein the metal comprises one or more of tungsten, titanium, aluminum, lanthanum and molybdenum.

14. The method of claim 12, wherein the metal nitride and metal silicide surfaces comprise one or more of TiN, MoN, LaN, TiSiN, TaN, TaSiN, MoSiₓ, TaSiₓ, and WN.

15. The method of claim 12, wherein the oxide is selected from the group consisting of SiO₂, Al₂O₃, ZrO₂, HfO₂, La₂O₃ and combinations thereof.

16. The method of claim 15, wherein the oxide is deposited utilizing a process selected from the group consisting of atomic layer deposition (ALD), chemical vapor deposition (CVD), pulsed chemical vapor deposition (pCVD) and physical vapor deposition (PVD).

17. The method of claim 12, wherein selectively depositing the molybdenum film comprises a pulsed chemical vapor deposition (pCVD) process.

18. The method of claim 12, wherein selectively depositing the molybdenum film comprises an atomic layer deposition (ALD) process).

19. The method of claim 12, wherein the bottom surface comprises titanium nitride.

20. The method of claim 19, wherein the oxide comprises La2O3.
